(19) United States
(12) Patent Application Publication
(10) Pub. No.: US 2026/0308804 A1
(43) Pub. Date: Oct. 8, 2026

(54) METHOD AND APPARATUS FOR SUPPRESSION OF DEFECTS DURING GALLIUM OXIDE EPITAXY

(71) Applicant: Kyma Technologies, Inc., Raleigh (NC)

(72) Inventors: Jacob H Leach, Raleigh, NC (US); Heather A. Splawn, Raleigh, NC (US); Kevin Udwary, Raleigh, NC (US)

(21) Appl. No.: 19/482,673

(22) PCT Filed: May 15, 2024
(86) PCT No.: PCT/IB2024/054739

§ 371 Date: Nov. 7, 2025

Related U.S. Application Data
(60) Provisional application No. 63/502,436, filed on May 16, 2023.

(51) Int. Cl. C30B 25/14; C30B 25/08; C30B 25/10; C30B 25/16; C30B 29/16

(52) U.S. Cl. CPC C30B 25/14; C30B 25/08; C30B 25/10; C30B 25/16; C30B 29/16

(57) ABSTRACT

The present disclosure provides a reaction system for growing gallium oxide films, including a reaction chamber housing a substrate; a source of gallium halide gas in fluid communication with the reaction chamber via a first gas injector positioned to direct the gallium halide gas toward the substrate; a source of oxygen-containing gas in fluid communication with the reaction chamber via a second gas injector positioned to direct the oxygen-containing gas toward the substrate; and a source of halogen-containing gas in fluid communication with the reaction chamber via a third gas injector positioned to direct the halogen-containing gas toward the substrate, the third gas injector positioned between the first and second gas injectors. A method growing a gallium oxide film epitaxially on a surface of a substrate is also provided.

### STATEMENT REGARDING FEDERALLY SPONSORED RESEARCH OR DEVELOPMENT

This invention was made with government support under grant number 80NSSC-22-C-A133 awarded by the National Aeronautics and Space Administration (NASA). The government has certain rights in the invention.

### FIELD OF THE INVENTION

The present disclosure relates to high quality single crystalline gallium oxide substrates, and methods and apparatuses for epitaxial growth of such substrates.

### BACKGROUND OF THE INVENTION

Monoclinic β—Ga₂O₃ has recently emerged as a promising material for “ultrawide” bandgap electronics for next-generation high voltage lateral and vertical power switching devices, in part due to its large bandgap (4.9 eV), high expected critical breakdown field (8 MV/cm), and its large high voltage and high frequency Baliga figures of merit. High-performance unipolar devices have been made with β—Ga₂O₃ substrate materials, including high voltage Schottky barrier diodes (SBDs), metal-semiconductor field-effect transistors (MESFETs), metal-oxide-semiconductor field-effect transistors (MOSFETs), and high-electron-mobility transistors (HEMTs).

Development of epitaxial growth techniques which support the production of high quality and thick homoepitaxial films of Ga₂O₃ for power devices with vertical architectures are still emerging, but the hydride vapor phase epitaxy (HVPE) technique, which is a chemically pure and high growth rate technology has been identified as a potentially suitable candidate, and small volumes of commercially available HVPE epilayers are now available.

In vertical devices, defects that give rise to unacceptably high leakage currents in, for example, Schottky barrier diodes, have been identified for Ga₂O₃ devices on (010), (−201), and (001) orientations, all of which are thought to arise from the same type of substrate-associated nano-void defect. For substrates grown by the edge-defined film-fed growth (EFG) technique, these defects have densities on the order of 10³-10⁴ cm⁻².

Additionally, microparticles which can form in the vapor phase under non-optimized growth conditions have been shown to promote sequences of stacking faults to form in epitaxial layers, which provide an additional leakage pathway in SBDs grown on (001) substrates. These defects can be highlighted using various alkaline treatments after epitaxy is complete, but are not generally observable in traditional X-ray rocking curve analyses. Nevertheless, the mitigation of both types of defects will be required to achieve high levels of performance in Ga₂O₃-based power devices. The formation of these defects is a particular challenge for HVPE films, which are grown at high growth rates, since there are more precursors available to pre-react under such growth conditions. There is a continuing need in the art to reduce or eliminate the production of microparticles during epitaxial growth of Ga₂O₃ substrates while simultaneously achieving commercially important high growth rates.

### SUMMARY OF THE INVENTION

The present disclosure relates to a system and method for epitaxial growth of Ga₂O₃ substrates that utilizes an excess free Cl₂ (or alternatively free HCl) injector in between the O₂ and GaCl injectors to suppress vapor phase pre-reactions, while maintaining high mass flow rates of the desired precursor flows (e.g., GaCl and O₂) so that a high growth rate can be maintained.

The present disclosure includes, without limitation, the following embodiments.
Embodiment 1: A reaction system for growing gallium oxide films, comprising: a reaction chamber housing a substrate; a source of gallium halide gas in fluid communication with the reaction chamber via a first gas injector positioned to direct the gallium halide gas toward the substrate; a source of oxygen-containing gas in fluid communication with the reaction chamber via a second gas injector positioned to direct the oxygen-containing gas toward the substrate; and a source of halogen-containing gas in fluid communication with the reaction chamber via a third gas injector positioned to direct the halogen-containing gas toward the substrate, the third gas injector positioned between the first and second gas injectors.
Embodiment 2: The reaction system of Embodiment 1, comprising a source of inert gas in fluid communication with the reaction chamber via one or more additional gas injectors positioned to direct the inert gas toward the substrate.
Embodiment 3: The reaction system of Embodiment 1 or 2, wherein the first, second, and third gas injectors have a substantially concentric arrangement comprising an inner gas injector proximal to a center of the substantially concentric arrangement, an intermediate gas injector adjacent to the inner injector and located further from the center than the inner gas injector, and an outer gas injector adjacent to the intermediate gas injector and located further from the center than the intermediate injector.
Embodiment 4: The reaction system of any one of Embodiments 1-3, wherein one of the first or second gas injectors is the inner gas injector, the third injector is the intermediate gas injector, and the other of the first or second gas injectors is the outer gas injector.
Embodiment 5: The reaction system of any one of Embodiments 1-4, further comprising one or more additional gas injectors within the substantially concentric arrangement, the one or more additional gas injectors positioned closer to the center than the inner gas injector and/or further form the center than the outer gas injector, the one or more additional gas injectors being in fluid communication with a source of inert gas. Embodiment 6: The reaction system of any one of Embodiments 1-5, wherein the source of gallium halide gas comprises a source of halogen-containing gas in fluid communication with liquid gallium.
Embodiment 7: The reaction system of any one of Embodiments 1-6, wherein the reaction chamber has a vertical orientation with the first, second, and third gas injectors positioned above the substrate.
Embodiment 8: The reaction system of any one of Embodiments 1-7, wherein the halogen-containing gas in fluid communication with the reaction chamber via the third gas injector comprises chlorine, such as gaseous HCl or Cl₂.
Embodiment 9: The reaction system of any one of Embodiments 1-8, wherein one or more of the source of gallium halide gas, the source of oxygen-containing gas, and the source of halogen-containing gas comprises at least one inert carrier gas, such as nitrogen or a noble gas.
Embodiment 10: A method growing a gallium oxide film epitaxially on a surface of a substrate, comprising: providing a substrate in a reaction chamber comprising a crystal growth zone overlying the substrate, the crystal growth zone being at a crystal growth temperature of about 800 °C or above, such as about 850 °C to about 1100 °C; injecting a gallium halide gas toward the substrate and into a first region of the crystal growth zone; injecting an oxygen-containing gas toward the substrate and into a second region of the crystal growth zone; and injecting a halogen-containing gas toward the substrate and into a third region of the crystal growth zone, the third region being between the first region and the second region; and depositing a gallium oxide film on a surface of the substrate.
Embodiment 11: The method of Embodiment 10, wherein the reaction chamber has a vertical orientation such that the gallium halide gas, the oxygen-containing gas, and the halogen-containing gas are injected above the substrate, and wherein the first region of the crystal growth zone is proximal to a center of the substrate and the second region is proximal to an outer edge of the substrate.
Embodiment 12: The method of Embodiment 10 or 11, wherein the pressure within the reaction chamber is about 50 to about 550 Torr, such as about 100 to about 300 Torr.
Embodiment 13: The method of any one of Embodiments 10-12, wherein the halogen-containing gas comprises chlorine, such as gaseous HCl or Cl₂.
Embodiment 14: The method of any one of Embodiments 10-13, wherein the partial pressure of the gallium halide gas injected into the crystal growth zone is about 0.10 Torr to about 10 Torr.
Embodiment 15: The method of any one of Embodiments 10-14, wherein a crystal growth rate of the gallium oxide film is about 8 μm/hr or higher, such as about 8 μm/hr to about 20 μm/hr or about 10 μm/hr to about 18 μm/hr.
Embodiment 16: The method of any one of Embodiments 10-15, wherein the molar ratio of O₂ to GaCl injected into the crystal growth zone is about 0.2 to about 2.0, such as about 0.3 to about 1.3.
Embodiment 17: The method of any one of Embodiments 10-16, wherein the molar ratio of the halogen in the halogen-containing gas to GaCl injected into the crystal growth zone is about 0.01 to about 1.0, such as about 0.02 to about 0.25.
Embodiment 18: The method of any one of Embodiments 10-17, wherein the average defect density of the gallium oxide film as measured by Etch Pit Density (EPD) is about 20×10³ cm⁻² or less, such as about 10×10³ cm⁻² or less.
Embodiment 19: The method of any one of Embodiments 10-18, wherein the substrate is a monoclinic Ga₂O₃ substrate and the gallium oxide film deposited thereon is a monoclinic gallium oxide film, and wherein there are no intervening buffer layers between the substrate and the gallium oxide film.
Embodiment 20: The reaction system of any one of Embodiments 1-9, wherein the substrate is a monoclinic Ga₂O₃ substrate.

These and other features, aspects, and advantages of the disclosure will be apparent from a reading of the following detailed description together with the accompanying drawings, which are briefly described below. The disclosure includes any combination of two, three, four, or more of the above-noted embodiments as well as combinations of any two, three, four, or more features or elements set forth in this disclosure, regardless of whether such features or elements are expressly combined in a specific embodiment description herein. This disclosure is intended to be read holistically such that any separable features or elements of the disclosure, in any of its various aspects and embodiments, should be viewed as intended to be combinable unless the context clearly dictates otherwise.

### BRIEF DESCRIPTION OF THE DRAWINGS

Having thus described the disclosure in the foregoing general terms, reference will now be made to the accompanying drawings, which are not necessarily drawn to scale, and wherein:

FIG. 1 illustrates a cross-sectional schematic view of an example reactor with injector apparatus suitable for use in the present disclosure;

FIG. 2 illustrates a cross-sectional schematic view of an example reactor of the same general type as FIG. 1 during crystal growth;

FIG. 3 is a schematic representation of another example injection apparatus suitable for use in the present disclosure;

FIG. 4 is a perspective view of an injector apparatus according to the present disclosure;

FIG. 5 is a bottom view of the injector apparatus of FIG. 4;

FIG. 6 is a cross-sectional side view of the injector apparatus of FIG. 4;

FIG. 7 is a cross-sectional side view of a different side of the injector apparatus of FIG. 4;

FIG. 8 is a cross-sectional side view of the injector apparatus of FIG. 4 detailing the liquid gallium chamber;

FIG. 9 illustrates surface morphologies after growth in five locations across a 2″ wafer prepared in Comparative Example A;

FIG. 10 illustrates a thickness map in μm units of a wafer prepared in Comparative Example A;

FIG. 11a illustrates a 20× Nomarski microscope image of the sample prepared at a crystal growth pressure of 100 Torr in Comparative Example B;

FIG. 11b illustrates a 10× etched surface image of the sample prepared at a crystal growth pressure of 100 Torr in Comparative Example B;

FIG. 12a illustrates a 20× Nomarski microscope image of the sample prepared at a crystal growth pressure of 80 Torr in Comparative Example B;

FIG. 12b illustrates a 10× etched surface image of the sample prepared at a crystal growth pressure of 80 Torr in Comparative Example B;

FIG. 13a illustrates a 20× Nomarski microscope image of the sample prepared at a crystal growth pressure of 65 Torr in Comparative Example B;

FIG. 13b illustrates a 10× etched surface image of the sample prepared at a crystal growth pressure of 65 Torr in Comparative Example B;

FIG. 14 illustrates a thickness map in μm units of a second wafer prepared in Comparative Example B;

FIG. 15 illustrates an etched surface image in nine locations across a second wafer prepared in Comparative Example B;

FIG. 16a illustrates a 20× Nomarski microscope image of the sample prepared in the Inventive Example; and

FIG. 16b illustrates a 10× etched surface image of the sample prepared in the Inventive Example.

### DETAILED DESCRIPTION OF THE INVENTION

The present disclosure will now be described more fully hereinafter with reference to exemplary embodiments thereof. These exemplary embodiments are described so that this disclosure will be thorough and complete, and will fully convey the scope of the disclosure to those skilled in the art. Indeed, the present disclosure may be embodied in many different forms and should not be construed as limited to the embodiments set forth herein; rather, these embodiments are provided so that this disclosure will satisfy applicable legal requirements. As used in the specification, and in the appended claims, the singular forms “a”, “an”, “the”, include plural referents unless the context clearly dictates otherwise.

The terms “about” or “approximately” are defined as being close to as understood by one of ordinary skill in the art. In one non-limiting embodiment the terms are defined to be within 10%, such as within 5%, or within 1%, or within 0.5%.

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

“Halogen” refers to elements within IUPAC group 17 of the periodic table, such as fluorine (F), chlorine (CI), and bromine (Br).

“Gallium oxide” refers to any phase of Ga₂O₃ (e.g., alpha-phase or beta-phase). The present disclosure also extends to production of alloys of gallium oxide in combination with other elements, including Al or In (such as (AlₓGa₁₋ₓ)₂O₃ or (InₓGa₁₋ₓ)₂O₃).

### Reaction System

The present disclosure provides a reaction system suitable for use in growing gallium oxide (e.g., β—Ga₂O₃) homoepitaxial films or alloys thereof, particularly using HVPE growth techniques. However, principles of the present disclosure could also be applied to other vapor-phase chemical deposition crystal growth methods, such as metal organic chemical vapor deposition (MOCVD). The reactor system of the present disclosure includes an injector adapted to direct reagent gases towards a substrate, and additionally adapted to direct a halogen-containing gas towards the substrate in an intermediate position between two reagent gases. Although not bound by a theory of operation, it is believed that use of the halogen-containing gas as a buffer between two reactive gases can reduce or eliminate vapor phase pre-reactions between the reactive gases that can lead to deleterious macroscopic or microscopic particles imbedded in the epitaxial layer grown on a substrate. In certain embodiments, this reduction in defects can be accomplished without sacrificing high crystal growth rates.

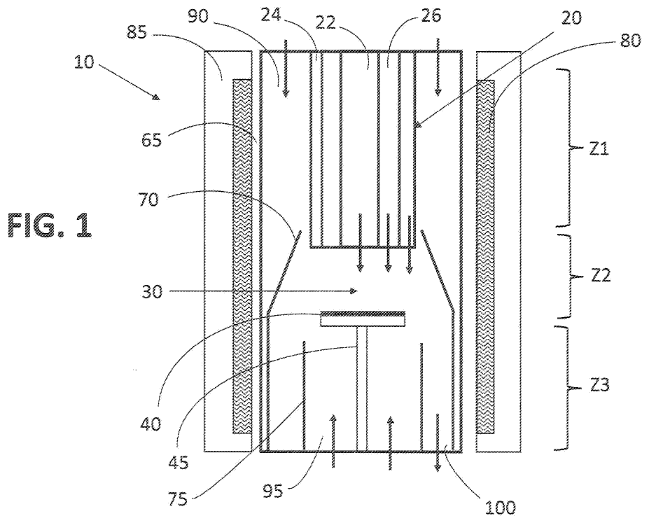

FIG. 1 provides a schematic view of a portion of an example embodiment of a reactor 10 suitable for use in the present disclosure. The reactor 10 includes a reaction chamber 30 having an injector apparatus 20 positioned therein. The injector apparatus 20 can comprise three concentrically-arranged injectors 22, 24, 26. The centrally-located injector 22 can be used for a first reagent gas, such as a gallium halide gas. The outermost injector 24 can be used for a second reagent gas, such as an oxygen-containing gas (e.g., purified oxygen or air). The injector 26 in the intermediate position between the reagent gas injectors 22, 24 is adapted for use with a halogen-containing gas, such as a gas containing HCl or Cl₂. Through such an injector apparatus 20, the reagent gases are delivered to a crystal growth space within the reaction chamber 30 overlying a substrate 40 for subsequent reaction near the surface of the substrate for purposes of growing an epitaxial layer of, for example, β—Ga₂O₃. Again without being bound by any particular theory of operation, the presence of the halogen-containing gas injected between the two reagent gases has been found to either suppress undesirable reactions in the crystal growth space that can lead to particle defects in the grown epitaxial layer or scavenge and remove such particles from the surface of the epitaxial layer during crystal growth.

As shown, the substrate 40 can be supported by support 45, which is optionally translatable between a raised crystal growth position closer to the injector apparatus 20 (as shown) and a lowered position where the substrate can be accessed and removed/replaced. The reaction chamber 30 can be defined, for example, by an outer wall 65, an inner wall 70 having a portion slanted inward toward the crystal growth space and arranged such that an end of the inner wall is proximal to an end of the injector apparatus 20, and a substate support wall 75 defining a space through which the support 45 can be moved back and forth from the raised crystal growth position to a lowered position for substrate access.

The substrate support 45, outer wall 65, inner wall 70, and substrate support wall 75 can be constructed of any material inert and thermally stable at crystal growth temperatures as noted below. Example materials include quartz, alumina, silicon carbide, tantalum carbide, and the like. The inner wall 70 and the substrate support wall 75 are advantageously positioned proximal to the injected gaseous reagents and can therefore aid in reducing or eliminating deposits on the outer wall 65. In this manner, the inner wall 70 and substrate support wall 75 can be viewed, in certain embodiments, as sacrificial liners that can be replaced as needed while preserving the outer wall 65 for long-term use.

Surrounding the outer wall 65 is a suitable heater 80 for maintaining the reaction chamber at desired crystal growth temperatures. An example heater 80 can include one or more resistive heating elements, typically surrounding by insulation 85 to reduce heat loss. In certain embodiments, the heater 80 is capable of independent heating control in multiple zones. The total number of zones may vary. As shown, the zones can include a first zone Z1 in the area of the injector apparatus 20 overlying the crystal growth space, a second zone Z2 in the area of the crystal growth space, and a third zone Z3 below the substrate 40. Additional zones are also possible, such as zones proximal to the top of the reactor and/or an upper portion of the injector apparatus 20 (not shown).

It is advantageous in certain embodiments to also inject an inert gas into various locations of the reaction chamber 30. As shown, in one embodiment, an inert gas is injected into a first area 90 surrounding the injector apparatus 20 and a second area 95 within the substrate support wall 75. In this manner, deposition of material in undesirable locations of the reaction chamber 30 can be reduced or eliminated. The reactor 10 can also include a suitable exhaust port 100 for removal of gases from the reaction chamber 30.

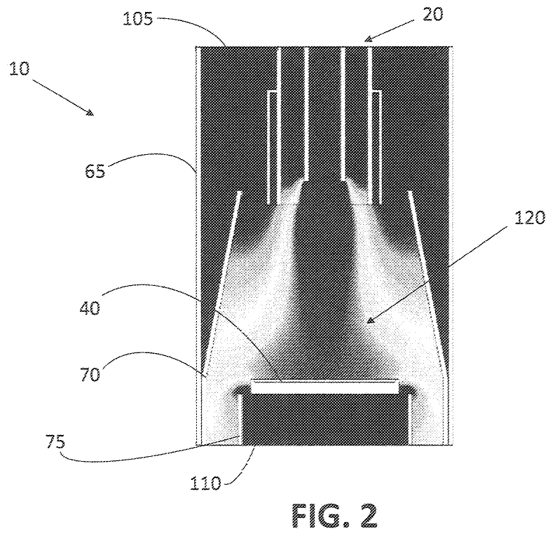

FIG. 2 schematically illustrates a reactor 10 of the same general configuration shown in FIG. 1 during crystal growth. As shown, the gaseous reagents and the halogen-containing gas are directed from the injection apparatus 20 toward the substrate 40 and into a crystal growth space 120. The darker areas 105, 110 underneath the support 40 and surrounding the injection apparatus 20 are areas in which inert gases are injected in order to suppress reagent gases from entering those areas.

Although FIGS. 1 and 2 show a reactor 10 with a vertical orientation, the present disclosure is not limited to such an orientation. The same general principles of the present disclosure could be applied to other reactor orientations, such as horizontal reactors where reagents are injected laterally into a reaction chamber. In addition, the present disclosure is not limited to an injector apparatus with concentrically arranged injectors. An injector apparatus with side-by-side injectors could also be utilized without departing from the present disclosure. The relative location of the injector for the two reagent gases could also change from the arrangement shown in FIGS. 1 and 2 without departing from the present disclosure. For example, the position of injection the two reagent gases could be switched with the oxygen-containing gas injected through the centrally-located injector 22 and the gallium halide gas injected through the outermost injector 24.

Still further, even where a concentric arrangement is utilized with one or more injectors configured in a ring-like or annular shape, the concentric arrangement need not be precisely concentric, meaning each injector need not have the same precise center. Instead, the injector apparatus could be substantially concentric, meaning concentric rings with a relatively small offset in the center of each concentric ring are included.

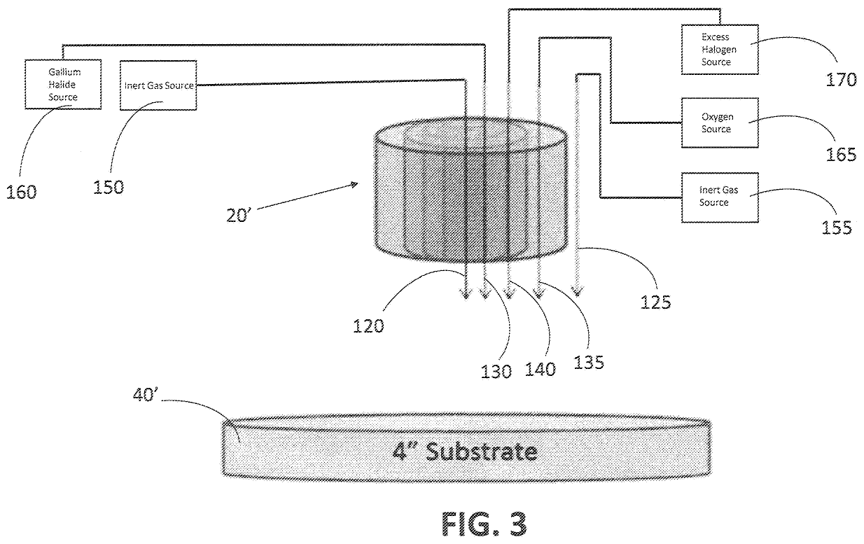

The number of rings within a substantially concentric arrangement can also vary. The example embodiment of FIGS. 1 and 2 illustrate an injector with three concentric injectors. However, other arrangements with additional substantially concentric injectors could also be used. A further embodiment of such an arrangement is shown in FIG. 3, which schematically illustrates a portion of an injector apparatus 20′ with five concentric injectors positioned to direct gases towards a substrate 40′. As shown, such an injector 20′ may include substantially concentric injectors that includes two injectors for inert gas flow 120, 125, one arranged centrally within the injector apparatus and one positioned as the outermost injector. Between the two inert gas flows are injectors for the two reagent gases, 130, 135 and an injector for the halogen-containing gas 140 positioned between the reagent gas injectors.

Each gas flow is in fluid communication with a source for each gas. For example, as shown, the two injectors for inert gas flow 120, 125 are in fluid communication with inert gas sources 150, 155. It is of course apparent that a single inert gas source could be used for both injectors for inert gas flow. One of the reagent gas injectors 130 can be in fluid communication with a gallium halide source 160 and the other of the reagent gas injectors 135 can be in fluid communication with an oxygen-containing gas source 165. The injector for the halogen-containing gas 140 can be in fluid communication with a halogen-containing gas source 170.

The various gas sources may vary. The inert gas source is typically nitrogen or a noble gas, such as argon or other members of IUPAC group number 18 within the periodic table. The oxygen source is typically purified oxygen or air, which is typically used in a dry or low moisture form. In certain embodiments, the oxygen source is a commercially available semiconductor grade oxygen-containing gas, such as commercially available mixtures of oxygen with nitrogen or argon. The halogen-containing gas is typically gaseous HCl or Cl₂, although other halogen gases could also be used. The gallium halide source is typically GaCl, although other gallium halides could be used, such as other compounds containing gallium and a different halogen. In certain embodiments, the gallium chloride is formed in situ within the reaction system by flowing either a combination of Cl₂ and H₂ or gaseous HCl over liquid gallium within an injector apparatus as explained more fully below. An inert gas can be combined with any of the other gas sources, such as the GaCl gas, the oxygen-containing gas, or the halogen-containing gas.

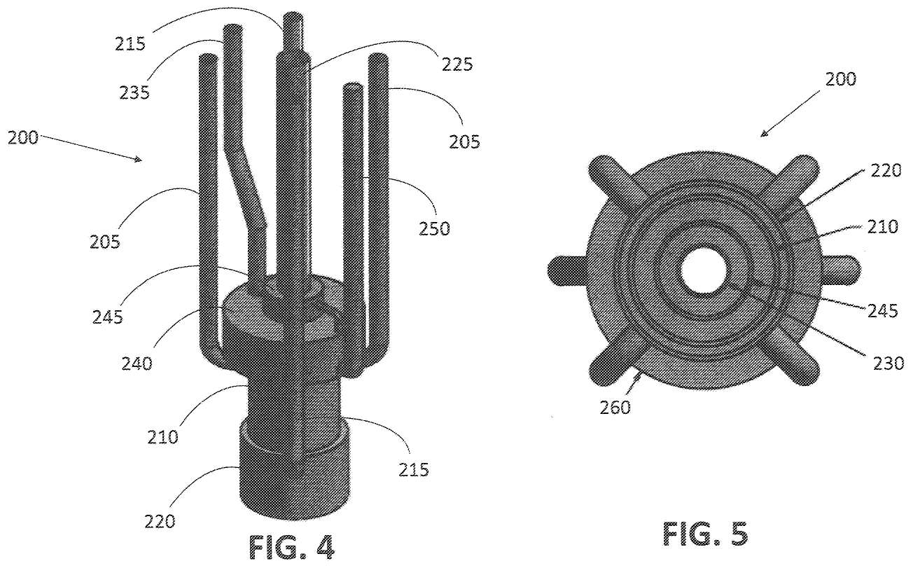

A further example of an injection apparatus suitable for use in the present disclosure is set forth in FIGS. 4-9. As shown in FIG. 4, the injection apparatus 200 can include piping for delivery of the various gas flows into multiple concentric injectors within the injection apparatus. The piping can include multiple intake pipes 205 for delivery of the halogen-containing gas into an intermediate ring injector 210 of the injection apparatus 200 and multiple intake pipes 215 for delivery of the oxygen-containing gas into an outer injector 220 of the injection apparatus. A central pipe 225 can deliver an inert gas flow to the central injector 230 (see FIG. 5) within the injection apparatus 200. An intake pipe 235 for a mixture of Cl₂ and H₂ (or HCl) is provided in fluid communication with a liquid gallium chamber 240 for in situ formation of GaCl that can be delivered to an injector 245 positioned annularly around the central injector 230. The injector apparatus 200 can further include one or more support posts 250 that are not adapted for fluid flow. A bottom view of the injector of FIG. 4 is shown in FIG. 5, which illustrates each concentric injector as described above. In certain embodiments, the injector apparatus 200 can be used in combination with a further inert gas injector (not shown) that injects an inert gas around the outer surface 260 of the injection apparatus.

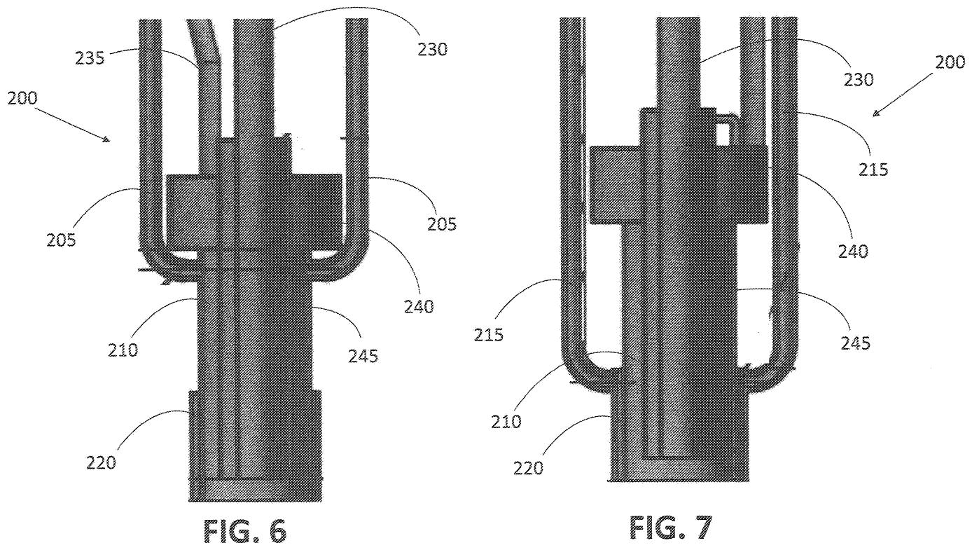

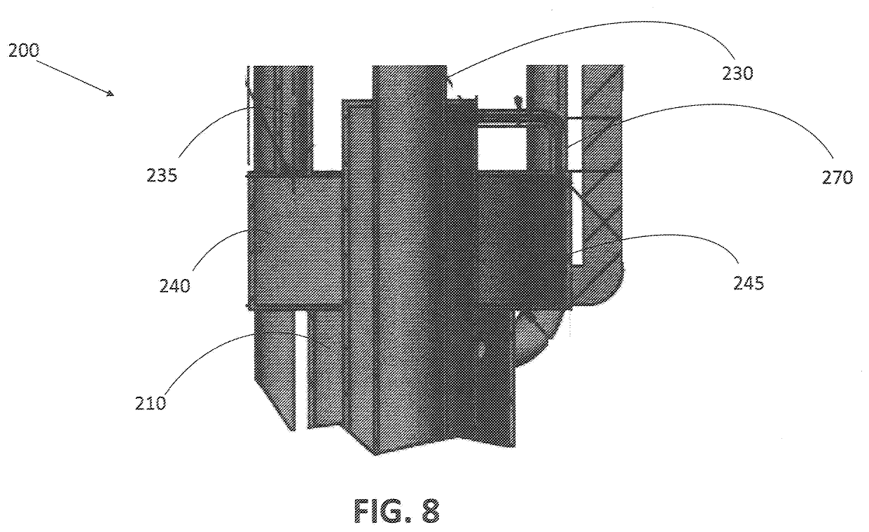

FIGS. 6 and 7 provide cross-sectional side views of the injector apparatus 200 of FIG. 4. FIG. 8 provides a more detailed cross-sectional view of the liquid gallium chamber 240 and illustrates the intake pipe 235 in fluid connection with the liquid gallium chamber and an outlet pipe 270 for fluid transfer of the gallium halide from the liquid gallium chamber to the injector 245.

### Gallium Oxide Crystal Growth Process

The present disclosure also provides a method growing a Ga₂O₃-based single crystal film epitaxially on a surface of a substrate. The method can be practiced, for example, with the reaction systems described above. The method involves providing a substrate in a reaction chamber comprising a crystal growth zone overlying the substrate, the crystal growth zone being at a crystal growth temperature. Example crystal growth temperatures include about 800 °C or above, such as about 850 °C to about 1100 °C or about 900 to about 1000 °C. The pressure within the reaction chamber during crystal growth is typically about 50 to about 550 Torr, such as about 100 to about 300 Torr.

The substrate used for crystal growth may vary, but is typically either sapphire or a β—Ga₂O₃ substrate. The crystalline orientation of the Ga₂O₃ substrate may vary, with one advantageous example being the (001) orientation. Substrate sizes may vary, with typical diameter ranges including about 2 to about 12 inches, such as about 4 to about 8 inches.

The method and apparatus of the present disclosure are particularly well-suited for homoepitaxial growth of monoclinic Ga₂O₃ films (i.e., β—Ga₂O₃) on a monoclinic Ga₂O₃ substrate. Thus, in such embodiments, no buffer layers are required or desired. In some embodiments of the present disclosure, the method described herein is practiced in the absence of any buffer layers between the substrate and the Ga₂O₃ film, meaning there are no intervening layers (such as metal oxide containing layers) deposited between the substrate and the monoclinic Ga₂O₃ film. Instead, the monoclinic Ga₂O₃ film is in direct contact with the substrate surface.

Alternatively, for heteroepitaxial growth of, e.g., Ga₂O₃ with corundum phase on sapphire, one or more buffer layers accommodating lattice constant and/or thermal expansion coefficient differences between the Ga₂O₃ and the sapphire substrate may be utilized.

Prior to growth, the substrate wafers are typically cleaned using a series of solvents to remove organic residues, as well as a series of acids, for example aqueous HCl and/or HF acid, to remove metallic impurities or reconstructed suboxides from the wafer surface. Substrate wafers are subsequently rinsed in deionized water and blown dry with nitrogen before being loaded into the reactor.

The method involves injecting a gallium halide gas toward the substrate and into a first region of the crystal growth zone and injecting an oxygen-containing gas toward the substrate and into a second region of the crystal growth zone. Still further, the method includes injecting a halogen-containing gas toward the substrate and into a third region of the crystal growth zone, the third region being between the first region and the second region. For example, the halogen-containing gas can be injected through an injector positioned between the oxygen-containing gas and the gallium halide gas as described above. In this manner, the halogen-containing gas provides “excess” halogen to the crystal growth zone in a buffer region between the point of injections of the oxygen-containing gas and the gallium halide gas, which is believed to suppress undesirable vapor phase pre-reactions that can lead to particle defects in the grown β—Ga₂O₃ film. In certain embodiments, the reaction chamber has a vertical orientation such that the gallium halide gas, the oxygen-containing gas, and the halogen-containing gas are injected above the substrate, and wherein the first region of the crystal growth zone is proximal to a center of the substrate and the second region is proximal to an outer edge of the substrate.

The partial pressure of the reagent gases during crystal growth can vary. Example partial pressures for GaCl include from about 0.10 Torr to about 10 Torr, such as about 0.2 to about 2.5 Torr. The amount of oxygen injected into the reaction chamber can be defined as a molar ratio of O₂ to GaCl, with example ranges including ratios of about 0.2 to about 2.0 or about 0.3 to about 1.3. The amount of added halogen-containing gas can be expressed as a molar ratio of added halogen (e.g., Cl₂) to GaCl, with example ranges including ratios of about 0.01 to about 1.0 or about 0.02 to about 0.25.

The addition of the halogen-containing gas to the reaction chamber can enable high-quality crystal growth at advantageously high crystal growth rates. For example, in certain embodiments, the crystal growth rate can be about 8 μm/hr or higher or about 10 μm/hr or higher or about 12 μm/hr or higher, such as about 8 μm/hr to about 20 μm/hr or about 10 μm/hr to about 18 μm/hr or about 12 μm/hr to about 16 μm/hr.

Despite these high crystal growth rates, the defect density of the grown crystal as measured by Etch Pit Density (EPD) remains relatively low. In certain embodiments, the average defect density measured at multiple points, for example 5 points, is about 20×10³ cm⁻² or less, such as about 10×10³ cm⁻² or less, with example ranges being about 1×10³ cm⁻² to about 20×10³ cm⁻² or about 5×10³ cm⁻² to about 15×10³ cm⁻².

Quality of the grown film can also be measured using X-Ray diffractometer (XRD) analysis. In certain embodiments, the grown film exhibits a full-width at half-maximum (FWHM) of the (004) reflection of about 35 arcsec or less, such as about 30 arcsec or less or about 25 arcsec or less, with example ranges including about 15 to about 35 arcsec or about 20 to about 30 arcsec.

The thickness of the grown film can vary and will depend on the desired application for the film. In certain embodiments, the method of the present disclosure can be used to produce films having an average thickness as measured by Fourier-transform infrared spectroscopy (FTIR) of at least about 5 μm or at least about 10 μm or at least about 15 μm, such as thickness ranges of about 5 μm to about 20 μm or about 10 μm to about 18 μm.

### EXPERIMENTAL

### Substrate Analysis Techniques

### Fourier-transform Infrared Spectroscopy (FTIR)

After growth, thicknesses of an epitaxial layer were estimated both by measuring the change in weight of the wafers during the crystal growth time period, as well as by Fourier-transform infrared spectroscopy (FTIR). The evaluation of epilayer thickness by FTIR measurement is carried out by fitting the measured interference peaks from the IR reflectance to a calculated set of interference peaks, over a range of, for example, 700-1500 wavenumbers (cm⁻¹).

### Etch Pit Density (EPD)

Evaluation of the density of stacking faults was evaluated by etching the epitaxial layers in a KOH bath (11.7 M) for 30 minutes at 100 °C and evaluating the etched surface using an optical microscope. The pit-like features which appear after the KOH etching are easily discerned under an optical microscope.

Prior to subjecting the layers to the KOH bath, it is sometimes beneficial to subject the film to a polishing process so that the pit-like features are more easily discerned. The polishing process may consist of one or more mechanical lapping steps using an abrasive like SiC or diamond, followed by a chemical-mechanical polishing (CMP) process using an alkaline slurry with an abrasive such as silica.

### X-Ray Rocking Curves

The structural perfection of crystalline substrates is commonly evaluated by means of x-ray diffraction measurements known as x-ray rocking curves (XRRCs). The width of the rocking curve peak measured from a given x-ray reflection of a crystalline material probes the degree of ordering of the crystal's lattice planes associated with the specified reflection.

Using a high resolution X-ray diffractometer (X-Pert Pro), optimizations along both the omega and chi axes of the goniometer about the (004) reflection of Ga₂O₃ were performed before collecting a final omega scan of the (004) reflection. The structural quality was then assessed by evaluating the full-width at half-maximum (FWHM) of the (004) reflection.

### Comparative Example A

Homoepitaxial β—Ga2O3 films were grown on commercially available (001) substrates in a 4″-capable hydride vapor phase epitaxy (HVPE) deposition system with three concentric injectors. GaCl was generated using a combination of Cl₂/H₂flowed over liquid gallium and injected in the central injector and dry air was injected as the O₂ source through the outermost injector. N₂ was injected as an inert gas from the intermediate injector. The temperature of the growth zone was about 950 °C, and the growth pressure was about 100 Torr. The O₂:GaCl molar ratio was 0.38.

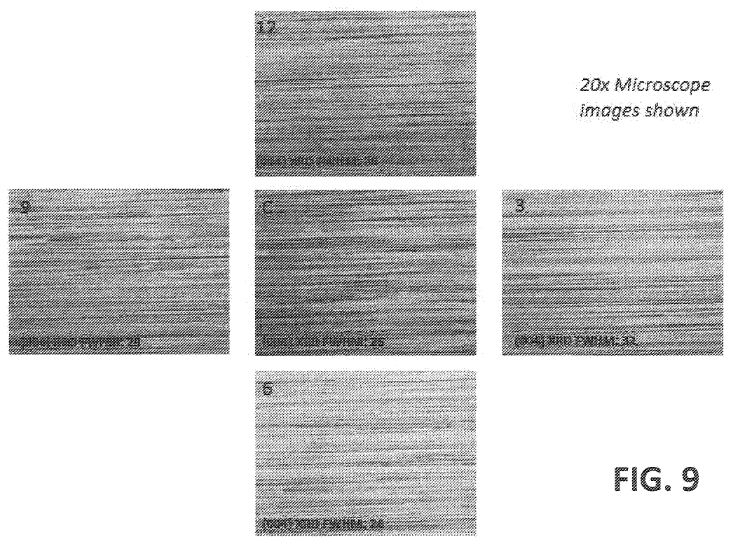

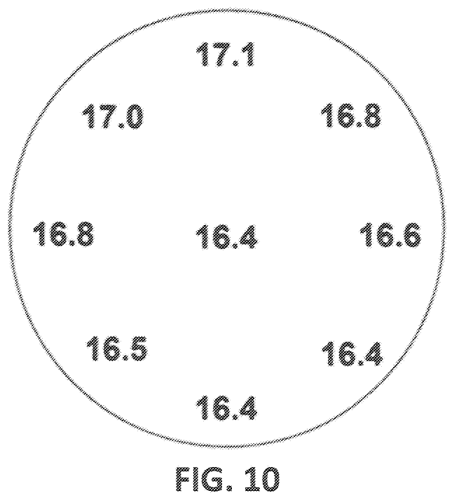

A first β—Ga 2O3 film was grown under the conditions noted above to a thickness of about 16-17 μm. The growth rate was 4.8 μm/hr for this film, as measured by the change in weight of the sample before and after growth. FIG. 9 shows surface morphologies after growth in five locations across a 2″ wafer, along with the XRD linewidths (inset) for the (004) reflections in those same locations (FWHM varied from 24 to 32 arcsec across the five measurement locations). FIG. 10 shows a thickness map in μm units by FTIR of the same film and the average thickness was 16.7 μm±3%. The surface morphology over this whole 2″ wafer appeared to be uniform and smooth, and the thickness uniformity is better than 5% over the whole wafer.

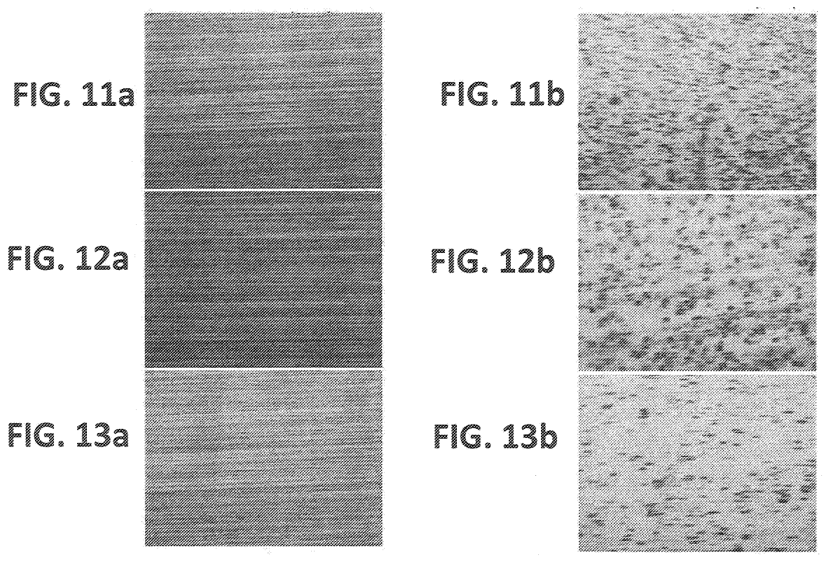

Evaluation of the density of killer stacking fault defects was performed on another wafer which was grown under identical conditions, but with a thickness of only ~5 μm. Etch pit density (EPD) was qualitatively assessed by evaluating the density of pit features on the wafer surface after subjecting the film to 30 minutes of hot (100 °C) KOH as described above. A 20× Nomarski microscope image of the surface is shown in FIG. 11a and a 10× of the etched surface is shown in FIG. 11b. The defects shown in the EPD image, which appear visually in FIG. 11b as dark spots, appears to be significantly higher than that of the estimated density of defects in the starting substrate (expected to be in the high 10³ cm⁻² range). This suggests that the origin of the defects may be from vapor phase pre-reactions.

### Comparative Example B

In order to reduce the propensity for the pre-reaction to occur, the gas velocity in the reactor was increased by reducing the growth pressure from 100 Torr to 80 Torr and to 65 Torr, but otherwise using the same system and reaction conditions of Comparative Example A. This reduction in growth pressure also reduced the growth rates from about 4.7 μm/hr (100 Torr), to about 4.0 μm/hr (80 Torr), to about 3.1 μm/hr (65 Torr). Films were grown to thicknesses of ~5 μm on small wafer pieces under each of these conditions. The wafer pieces were polished before EPD analysis. Images of the as-grown surface and the surface after KOH etching for the film grown at 80 Torr are provided as FIG. 12a (20× Nomarski microscope image) and FIG. 12b (10× etched surface image). Images of the as-grown surface and the surface after KOH etching for the film grown at 65 Torr are provided as FIG. 13a (20× Nomarski microscope image) and FIG. 13b (10× etched surface image). As shown, reducing the crystal growth pressure reduced the defect density, as shown visually as a reduction in dark spots shown in FIGS. 12b and 13b. The film grown at 65 Torr exhibited an etch pit density nearly as low as the starting substrate.

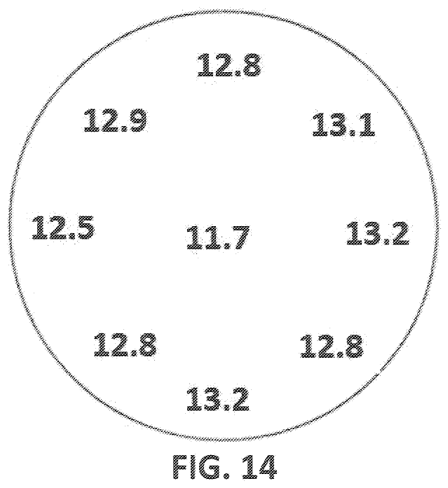

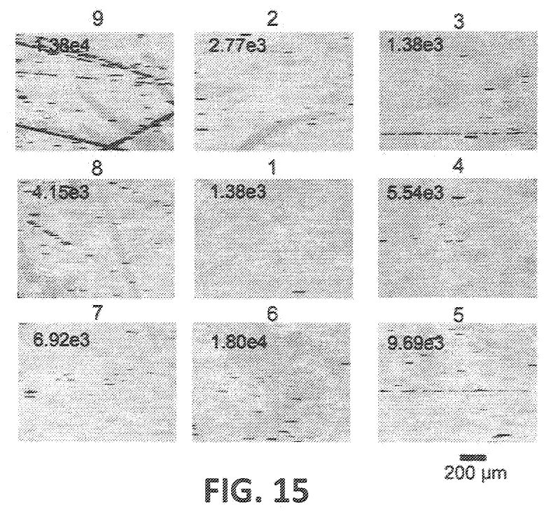

Next, the above experimental conditions at 65 Torr were repeated for a longer growth time on a 2″ (001) substrate in order to assess the growth uniformity and evaluate the EPD over an entire 2″ wafer area for a ~15 μm thick film. FIG. 14 shows a thickness map by FTIR of the resulting film and the average thickness was 12.8 μm±8%. FIG. 15 shows the surface after KOH etching in nine locations, illustrating that the EPD for this epilayer is similar to that of the starting substrate. For FIG. 15, position ‘1’ is the wafer center, ‘2’ is the 12 o'clock position, and subsequent images (3, 4, 5 . . . ) are clockwise from 12 o'clock.

FTIR analysis of the epilayer thickness suggested that the growth rate for this film was only 1.8 μm/hr. The lower-than-anticipated growth rate was likely either due to discrepancies between FTIR and weight-based thickness analyses or differences stemming from loading effects in the reactor when using a whole 2″ wafer vs. a small test piece. From these images, the average EPD was 7.1×10³ cm⁻², which is in line with the estimated defect density associated with the substrate itself. This example illustrates that reducing the growth pressure can reduce EPD in the grown film, but at the expense of sharply reduced growth rate.

### Inventive Example

The same general reaction system and growth conditions of the above Comparative Examples were used, except with a growth pressure of 120 Torr and using an injected Cl₂ gas carried in an N₂ carrier gas positioned between the O₂ injector and the GaCl injector (instead of inert gas only as used in Comparative Examples). The growth temperature was 950 °C, the O₂:GaCl molar ratio was 0.32, and the molar ratio of added Cl₂ (added through intermediate injector) to GaCl was 0.04. A~15 μm thick epilayer was grown under these conditions.

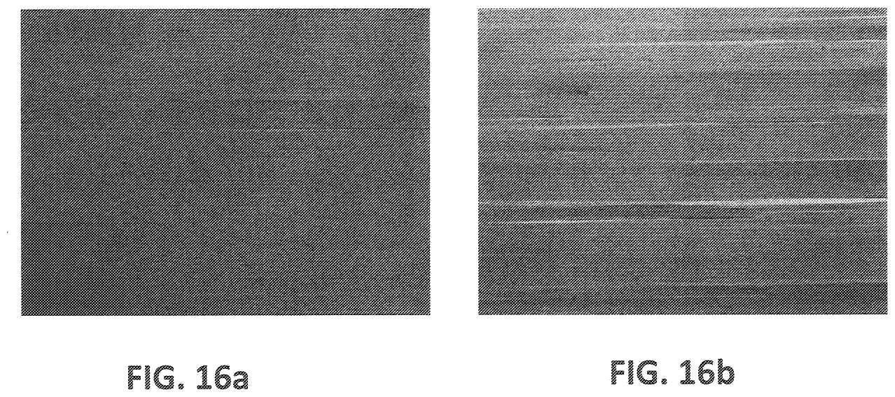

EPDs were evaluated as noted above in all layers and Nomarski microscope images of the final result are given in FIG. 16a (20× Nomarski microscope image) and FIG. 16b (10× etched surface image). The final growth rate realized was 14.1 μm/hr. The film exhibited an XRD linewidth of the (004) reflection of 26 arcsec, a very smooth surface morphology, and exhibited very few discernable etch pits after being subjected to the 30 min KOH etch process described above.

This result indicates that use of the injected Cl₂ gas positioned between the two reagent gases reduced vapor phase pre-reactions as evidenced by the superior EPD result as compared to the Comparative Examples grown at similar growth pressure, but without the injected excess Cl₂ gas. Additionally, the reduction in defect density was achieved without reduction in growth rate.

Many modifications and other aspects of the disclosure set forth herein will come to mind to one skilled in the art to which the disclosure pertains having the benefit of the teachings presented in the foregoing descriptions and the associated drawings. Therefore, it is to be understood that the disclosure is not to be limited to the specific aspects disclosed and that modifications and other aspects are intended to be included within the scope of the claims. Although specific terms are employed herein, they are used in a generic and descriptive sense only and not for purposes of limitation.

1. A reaction system for growing gallium oxide films, comprising:
a reaction chamber housing a substrate;
a source of gallium halide gas in fluid communication with the reaction chamber via a first gas injector positioned to direct the gallium halide gas toward the substrate;
a source of oxygen-containing gas in fluid communication with the reaction chamber via a second gas injector positioned to direct the oxygen-containing gas toward the substrate; and
a source of halogen-containing gas in fluid communication with the reaction chamber via a third gas injector positioned to direct the halogen-containing gas toward the substrate, the third gas injector positioned between the first and second gas injectors.

2. The reaction system of claim 1, comprising a source of inert gas in fluid communication with the reaction chamber via one or more additional gas injectors positioned to direct the inert gas toward the substrate.

3. The reaction system of claim 1, wherein the first, second, and third gas injectors have a substantially concentric arrangement comprising an inner gas injector proximal to a center of the substantially concentric arrangement, an intermediate gas injector adjacent to the inner injector and located further from the center than the inner gas injector, and an outer gas injector adjacent to the intermediate gas injector and located further from the center than the intermediate injector.

4. The reaction system of claim 3, wherein one of the first or second gas injectors is the inner gas injector, the third injector is the intermediate gas injector, and the other of the first or second gas injectors is the outer gas injector.

5. The reaction system of claim 3, further comprising one or more additional gas injectors within the substantially concentric arrangement, the one or more additional gas injectors positioned closer to the center than the inner gas injector and/or further form the center than the outer gas injector, the one or more additional gas injectors being in fluid communication with a source of inert gas.

6. The reaction system of claim 1, wherein the source of gallium halide gas comprises a source of halogen-containing gas in fluid communication with liquid gallium.

7. The reaction system of claim 1, wherein the reaction chamber has a vertical orientation with the first, second, and third gas injectors positioned above the substrate.

8. The reaction system of claim 1, wherein the halogen-containing gas in fluid communication with the reaction chamber via the third gas injector comprises chlorine, such as gaseous HCl or Cl₂.

9. The reaction system of claim 1, wherein one or more of the source of gallium halide gas, the source of oxygen-containing gas, and the source of halogen-containing gas comprises at least one inert carrier gas, such as nitrogen or a noble gas.

10. The reaction system of claim 1, wherein the substrate is a monoclinic Ga₂O₃ substrate.

11. A method growing a gallium oxide film epitaxially on a surface of a substrate, comprising:
providing a substrate in a reaction chamber comprising a crystal growth zone overlying the substrate, the crystal growth zone being at a crystal growth temperature of about 800 °C or above, such as about 850 °C to about 1100 °C;
injecting a gallium halide gas toward the substrate and into a first region of the crystal growth zone;
injecting an oxygen-containing gas toward the substrate and into a second region of the crystal growth zone; and
injecting a halogen-containing gas toward the substrate and into a third region of the crystal growth zone, the third region being between the first region and the second region; and
depositing a gallium oxide film on a surface of the substrate.

12. The method of claim 11, wherein the reaction chamber has a vertical orientation such that the gallium halide gas, the oxygen-containing gas, and the halogen-containing gas are injected above the substrate, and wherein the first region of the crystal growth zone is proximal to a center of the substrate and the second region is proximal to an outer edge of the substrate.

13. The method of claim 11, wherein the pressure within the reaction chamber is about 50 to about 550 Torr, such as about 100 to about 300 Torr.

14. The method of claim 11, wherein the halogen-containing gas comprises chlorine, such as gaseous HCl or Cl₂.

15. The method of claim 11, wherein the partial pressure of the gallium halide gas injected into the crystal growth zone is about 0.10 Torr to about 10 Torr.

16. The method of claim 11, wherein a crystal growth rate of the gallium oxide film is about 8 μm/hr or higher, such as about 8 μm/hr to about 20 μm/hr or about 10 μm/hr to about 18 μm/hr.

17. The method of claim 11, wherein the molar ratio of O₂ to GaCl injected into the crystal growth zone is about 0.2 to about 2.0, such as about 0.3 to about 1.3.

18. The method of claim 11, wherein the molar ratio of the halogen in the halogen-containing gas to GaCl injected into the crystal growth zone is about 0.01 to about 1.0, such as about 0.02 to about 0.25.

19. The method of claim 11, wherein the average defect density of the gallium oxide film as measured by Etch Pit Density (EPD) is about 20×10³ cm⁻² or less, such as about 10×10³ cm⁻² or less.

20. The method of claim 11, wherein the substrate is a monoclinic Ga₂O₃ substrate and the gallium oxide film deposited thereon is a monoclinic gallium oxide film, and wherein there are no intervening buffer layers between the substrate and the gallium oxide film.
